(19) United States
(12) Patent Application Publication
(10) Pub. No.: US 2014/0218081 A1
(43) Pub. Date: Aug. 7, 2014

(54) SEMICONDUCTOR DEVICE AND CLOCK DATA RECOVERY SYSTEM INCLUDING THE SAME

(71) Applicant: PANASONIC CORPORATION, Osaka (JP)

(72) Inventor: Akinori SHINMYO, Hyogo (JP)

(73) Assignee: PANASONIC CORPORATION, Osaka (JP)

(21) Appl. No.: 14/244,593

(22) Filed: Apr. 3, 2014

Related U.S. Application Data
(63) Continuation of application No. PCT/JP2012/002343, filed on Apr. 4, 2012.

(30) Foreign Application Priority Data
Oct. 28, 2011 (JP) 2011-237234

(51) Int. Cl. H03K 17/14

(52) U.S. Cl. CPC H03K 17/145
USPC 327/155; 327/212

(57) ABSTRACT

A semiconductor device includes a latch circuit. The latch circuit includes a sampling section that latches a differential input signal applied from a differential input node to the gates of a differential pair of transistors, a common adjusting section that adjusts a common potential of the differential input signal by adjusting based on a current control signal the amount of current that is drawn from the differential input node, and a common control section that controls the current control signal so that the differential pair of transistors operate in a saturated region, and supplies the controlled current control signal to the common adjusting section.

### CROSS-REFERENCE TO RELATED APPLICATIONS

This is a continuation of International Application No. PCT/JP2012/002343 filed on Apr. 4, 2012, which claims priority to Japanese Patent Application No. 2011-237234 filed on Oct. 28, 2011. The entire disclosures of these applications are incorporated by reference herein.

### BACKGROUND

The present disclosure relates to semiconductor devices including a latch circuit that latches a received signal, and clock data recovery systems.

FIG. 8 is a diagram showing a circuit configuration example of a latch circuit of the type that does not have a current source (e.g., Japanese Unexamined Patent Publication No. 2010-278544).

In a latch circuit 50 of FIG. 8, an NMOS transistor 50g is activated when a clock CK is at high level (at this time, a clock CKB is at low level). A current thus flows in resistors 50a, 50b and NMOS transistors 50c, 50d, whereby output signals OUT, OUTB change according to input signals IN, INB. An NMOS transistor 50h is activated when the clock CKB is at high level (at this time, the clock CK is at low level). A current thus flows in the resistors 50a, 50b and NMOS transistors 50e, 50f, whereby the output signals OUT, OUTB are latched.

This latch circuit 50 can achieve high-speed operation due to switching operation of the differential pair of NMOS transistors. This latch circuit 50 can also achieve a reduced power supply voltage because it does not have a current source.

Japanese Unexamined Patent Publication Nos. 2010-178094 and 2008-219678 describe a method using a replica circuit as a method for compensating for process, voltage, and temperature (PVT) variation.

### SUMMARY

However, since the latch circuit 50 of FIG. 8 does not have a current source, a common potential of the output signals OUT, OUTB varies due to PVT variation. For example, if the common potential of the output signals OUT, OUTB of the latch circuit 50 decreases, the NMOS transistors 50c, 50d operate in a non-saturated state, and gain of the latch circuit 50 decreases, thereby attenuating amplitude of the output signals OUT, OUTB. This increases a dead zone (e.g., a region where a signal decreases in amplitude and cannot be latched normally) near a signal transition point of a differential signal in the latch circuit 50, resulting in degradation in overall performance of a receiving system including the latch circuit 50. This problem is more significant in ultrahigh speed operation on the order of, e.g., gigahertz with a short time period between signal transition points, namely a short signal cycle, and in low amplitude operation with a low amplitude input signal a low-amplitude input signal on the order of, e.g., 100 millivolts.

Examples of a method for compensating for such variation in common potential due to PVT variation include methods using a replica circuit as described in Japanese Unexamined Patent Publication No. 2010-178094 or 2008-219678. However, in the techniques disclosed in Japanese Unexamined Patent Publication Nos. 2010-178094 and 2008-219678, variation in output signal due to PVT variation etc. is compensated for by adjusting the amount of current flowing in a bias current source that is used to drive the circuit. These techniques are therefore not applicable to latch circuits of the type that does not have a current source.

It is an object of the present disclosure to provide a configuration of a semiconductor device including a latch circuit, which is capable of suppressing reduction in gain of the latch circuit even if a common potential varies due to PVT variation etc.

According to a first aspect of the present disclosure, a semiconductor device includes a latch circuit. The latch circuit includes a sampling section that has a differential pair of transistors having their gates connected to a differential input node, and that latches a differential input signal applied from the differential input node to the gates of the differential pair of transistors, a common adjusting section that is configured to draw a current from the differential input node, and that adjusts a common potential of the differential input signal by adjusting based on a current control signal an amount of the current that is drawn from the differential input node, and a common control section that controls the current control signal so that the differential pair of transistors operate in a saturated region, and supplies the controlled current control signal to the common adjusting section.

In the first aspect, the common potential of the differential input signal is adjusted so that the differential pair of transistors operate in the saturated region, even if a common potential of nodes connected to drains of the differential pair of transistors vary due to PVT variation etc. This can prevent the differential pair of transistors from entering a non-saturated region due to, e.g., the variation in common potential of the nodes connected to the drains of the differential pair of transistors, and can suppress reduction in gain of the latch circuit and the semiconductor device including the same. This can suppress an increase in dead zone that occurs near a signal transition point. Accordingly, latch performance and signal reception performance of the semiconductor device can be ensured.

According to a second aspect of the present disclosure, a clock data recovery system includes: the semiconductor device of the first aspect; and a digital filter section that receives a signal sampled by the sampling section of the semiconductor device.

Including the semiconductor device of the first aspect in the clock data recovery system in this manner suppresses reduction in gain of the semiconductor device due to PVT variation. Overall performance of a reception system of the clock data recovery system can therefore be improved as compared to the case where the semiconductor device of the first aspect is not used.

According to the present disclosure, reduction in gain of the semiconductor device can be suppressed even if the common potential varies due to PVT variation etc. Reception performance of the semiconductor device and the clock data recovery system including the same can thus be ensured.

### BRIEF DESCRIPTION OF THE DRAWINGS

FIG. 1 is a diagram showing a configuration example of a semiconductor device according to a first embodiment.

FIG. 2 is a diagram showing another configuration example of a predetermined potential generating section.

FIG. 3 is a diagram showing another configuration example of the semiconductor device according to the first embodiment.

FIG. 4 is a diagram showing a configuration example of a semiconductor device according to a second embodiment.

FIG. 5 is a diagram showing a configuration example of a clock data recovery system.

FIG. 6 is a diagram showing a configuration example of a semiconductor device according to a third embodiment.

FIG. 7 is a diagram showing another configuration example of a common control section.

FIG. 8 is a diagram showing a configuration example of a conventional latch circuit.

### DETAILED DESCRIPTION

Embodiments of the present disclosure will be described below with reference to the accompanying drawings. In the following description of the embodiments, common components are denoted with the same reference characters, and detailed description thereof will be omitted.

### First Embodiment

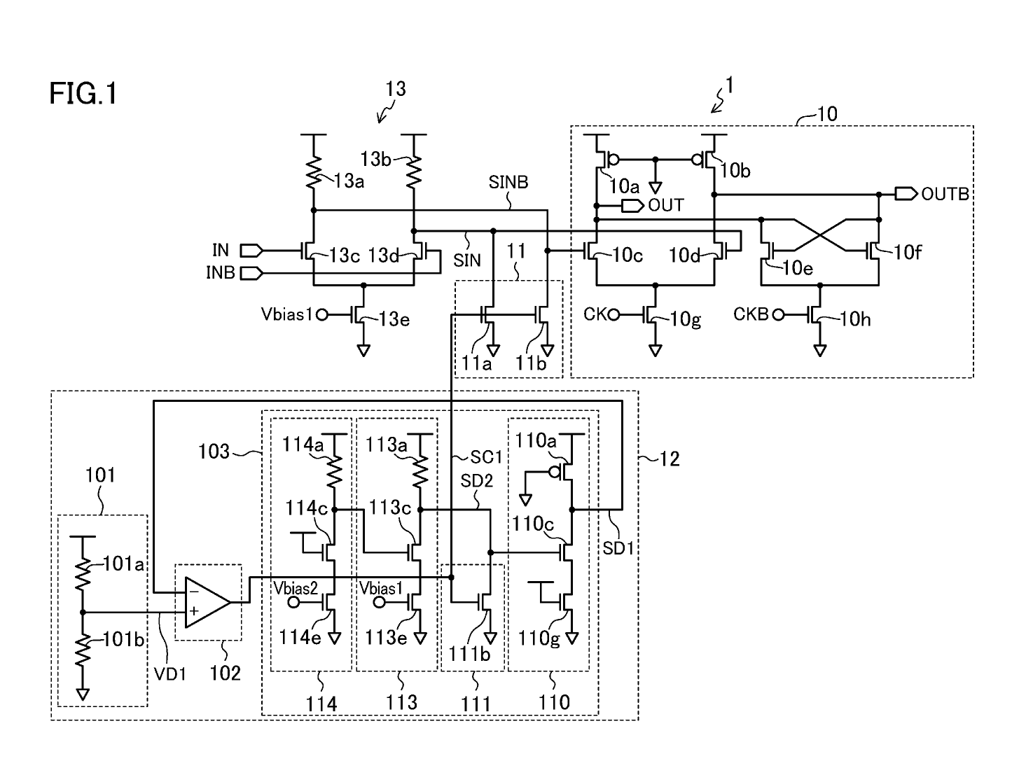

FIG. 1 is a diagram showing a circuit configuration example of a semiconductor device according to a first embodiment of the present disclosure.

A latch circuit 1 includes a sampling section 10, a common adjusting section 11, and a common control section 12.

The sampling section 10 includes: NMOS transistors 10c, 10d as a differential pair of transistors having their gates connected to differential input nodes SINB, SIN, respectively; NMOS transistors 10e, 10f as a holding circuit formed by a pair of transistors having their gates connected to the drains of the NMOS transistors 10d, 10c, respectively; an NMOS transistor 10g that receives a clock CK as a first clock signal at its gate to on/off control the NMOS transistors 10c, 10d; an NMOS transistor 10h that receives a clock CKB as a second clock signal at its gate to on/off control the NMOS transistors 10e, 10f; and PMOS transistors 10a, 10b as load circuits connected between a power supply and the NMOS transistors 10c, 10d and between the power supply and the NMOS transistors 10e, 10f, respectively, and having their gates connected to the ground.

Since the sampling section 10 thus does not have a current source, a reduced power supply voltage can be achieved. Since NMOS transistors are used as the differential pair of transistor and the transistors for holding data, high-speed operation can be achieved.

When the clock CK is at high level (at this time, the clock CKB is at low level) in the sampling section 10, the NMOS transistor 10g is activated and a current flows in the PMOS transistors 10a, 10b and the NMOS transistors 10c, 10d. Output signals that are output from output nodes OUT, OUTB respectively connected to the drains of the NMOS transistors 10c, 10d are switched to either high level or low level according to differential input signals that are input to the gates of the NMOS transistors 10c, 10d. In the following description, the output signals that are output from the output nodes OUT, OUTB are also denoted with “OUT,” “OUTB.” When the clock CKB is at high level (at this time, the clock CK is at low level), the NMOS transistor 10h is activated and a current flows in the PMOS transistors 10a, 10b and the NMOS transistors 10e, 10f. The output signals OUT, OUTB at the time the clock CKB is at high level are held by the PMOS transistors 10a, 10b and the NMOS transistors 10e, 10f.

An output amplifier 13 as an output circuit is connected to the preceding stage to the latch circuit 1. The output amplifier 13 includes a differential pair of transistors 13c, 13d, an NMOS transistor 13e receiving a bias Vbias1 at its gate, and resistors 13a, 13b as load circuits. The output amplifier 13 receives differential signals IN, INB at the gates of the NMOS transistors 13c, 13d as a differential pair of transistors, and outputs inverted amplified differential signals thereof to the differential input nodes SINB, SIN (i.e., the gates of the differential pair of transistors 10c, 10d of the sampling section 10) as the differential input signals. In the following description, the differential input signals output to the differential input nodes SINB, SIN are also denoted with “SINB,” “SIN.” Although not shown in the figure, a preamplifier having the same circuit configuration as the output amplifier 13 is connected in the preceding stage to the output amplifier 13.

The common adjusting section 11 includes NMOS transistors 11a, 11b as first and second transistors. The NMOS transistors 11a, 11b have their drains connected to the differential input nodes SIN, SINB (first and second nodes), respectively, and have their sources connected to the ground. A current control signal SC1 output from the common control section 12 is applied to the gates of the NMOS transistors 11a, 11b. In the common adjusting section 11, a current that is drawn from the differential input nodes SIN, SINB, i.e., the amount of current that flows in the NMOS transistors 11a, 11b, varies according to the voltage value of the current control signal SC1 applied to the gates of the NMOS transistors 11a, 11b. The current flowing in the NMOS transistors 11a, 11b flows to the resistors 13b, 13a of the output amplifier 13, whereby a common potential of the differential input signals SIN, SINB changes.

The common control section 12 includes a predetermined potential generating section 101, a differential amplifier 102, and a replica section 103.

The replica section 103 includes a replica sampling section 110 as a replica of a part of the sampling section 10, a replica common adjusting section 111 as a replica of a part of the common adjusting section 11, a replica output circuit 113 as a replica of a part of the output amplifier 13, and a replica 114 as a replica of a part of the preamplifier provided in the preceding stage to the output amplifier 13.

The replica sampling section 110 includes a PMOS transistor 110a connected between the power supply and an output node SD1, and NMOS transistors 110c, 110g as first replica transistors connected in series between the output node SD1 and the ground. The output node SD1 is connected to an inverting input terminal of the differential amplifier 102 described below. The gate of the PMOS transistor 110a is connected to the ground, and the gate of the NMOS transistors 110g is connected to the power supply. For example, the PMOS transistor 110a is a replica of the load circuit 10a, and the NMOS transistors 110c, 110g are replicas of the NMOS transistors 10c, 10g, respectively. A replica of the NMOS transistor 10d instead of the NMOS transistor 10c may be used as the NMOS transistor 110c, and a replica of the PMOS transistor 10b instead of the PMOS transistor 10a may be used as the PMOS transistor 110a.

The replica output circuit 113 includes a resistor 113a connected between the power supply and an output node SD2, and NMOS transistors 113c, 113e connected in series between the output node SD2 and the ground. The output node SD2 is connected to the gate of the NMOS transistor 110c of the replica sampling section 110. The bias Vbias1 is applied to the gate of the NMOS transistor 113e. For example, the resistor 113a is a replica of the resistor 13a, and the NMOS transistors 113c, 113e are replicas of the NMOS transistors 13c, 13e, respectively. A replica of the NMOS transistor 13d instead of the NMOS transistor 13c may be used as the NMOS transistor 113c, and a replica of the resistor 13b instead of the resistor 13a may be used as the resistor 113a.

The replica common adjusting section 111 includes an NMOS transistor 111b as a second replica transistor connected between the output node SD2 and the ground. An output node of the differential amplifier 102 described below is connected to the gate of the NMOS transistor 111b. For example, the NMOS transistor 111b is a replica of the NMOS transistor 11b. A replica of the NMOS transistor 11a instead of the NMOS transistor 11b may be used as the NMOS transistor 111b.

The replica 114 includes a resistor 114a connected between an output node and the power supply, and NMOS transistors 114c, 114e connected in series between the output node and the ground. The output node is connected to the gate of the NMOS transistor 113c of the replica output circuit 113. A bias Vbias2 is applied to the gate of the NMOS transistor 114e, and the gate of the NMOS transistor 114c is connected to the power supply. Although not shown in the figure, the resistor 114a and the NMOS transistors 114c, 114e of the replica 114 are replicas of a resistor and NMOS transistors which are included in the preamplifier provided in the preceding stage to the output amplifier 13, respectively.

In the replica section 103, the channel lengths and channel widths of the replica transistors (PMOS and NMOS transistors) and the original transistors (PMOS and NMOS transistors) are designed so as to make a current that is drawn into the common adjusting section 11 having the differential input nodes SIN, SINB connected thereto substantially equal to a current that is drawn from the output node SD2 having the drain of the NMOS transistor 111b connected thereto into the replica common adjusting section 111. Specifically, for example, the channel lengths and channel widths of the NMOS transistors 113c, 111b, 110c and the PMOS transistor 110a are designed to be substantially the same as those of the NMOS transistors 13c, 11b, 10c and the PMOS transistor 10a, respectively. The channel widths of the NMOS transistors 113e, 110g are designed to be substantially half the channel widths of the NMOS transistors 13e, 10g, respectively, and the channel lengths of the NMOS transistors 113e, 110g are designed to be substantially the same as those of the NMOS transistors 13e, 10g, respectively.

Each resistor included in the replica section 103 is designed to have substantially the same resistance value as the original resistor. For example, the resistor 113a is designed to have substantially the same resistance value as the resistor 13a.

In the replica 114 as well, the resistance value of the resistor and the transistor size are designed in a manner similar to that described above. This makes the amount of current that is drawn into the common adjusting section 11 substantially equal to that of current that is drawn into the replica common adjusting section 111.

As used in the present embodiment, the term “substantially” includes a margin of error of ±10%. The same applies to the following embodiments. The predetermined potential generating section 101 includes resistors 101a, 101b as first and second resistors connected in series between the power supply and the ground, and a predetermined potential node VD1 as an output node between the resistors 101a, 101b is connected to a non-inverting input terminal of the differential amplifier 102 described below. The predetermined potential generating section 101 thus outputs a voltage Vout resulting from voltage division by the resistors 101a, 101b and given by the following expression (1) to the non-inverting input terminal of the differential amplifier 102.

$$Vout = \frac{R 101 b}{R 101 a + R 101 b} \times Vvdd \qquad ( 1 )$$

In Expression (1), “R101a ” represents a resistance value of the resistor 101a, “R101b ” represents a resistance value of the resistor 101b, and “Vvdd” represents a power supply voltage. For example, if R101a=R101b, Vvdd/2 is output as the voltage value Vout.

The differential amplifier 102 compares a signal potential at the output node SD1 of the replica section 103 which is connected to the inverting input terminal with a signal potential at the predetermined potential node VD1 connected to the non-inverting input terminal, and outputs the current control signal SC1 that controls a potential to be applied to the gate of the NMOS transistor 111b, so as to make both signal potentials substantially equal to each other. Such a feedback configuration allows the signal potential at the output node SD2 of the replica common adjusting section 111, namely at the output node SD2 connected to the gate of the NMOS transistor 110c of the replica sampling section 110, to be adjusted so that the signal potential at the output node SD1 of the replica section 103 becomes substantially equal to that at the predetermined potential node VD1.

The current control signal SC1 is also applied to the gates of the NMOS transistors 11a, 11b of the common adjusting section 11, and the common potential of the differential input signals SIN, SIB is also adjusted to a value substantially equal to the signal potential that is applied to the gate of the NMOS transistor 110c. A common potential of the output signals OUT, OUTB of the sampling section 10 is thus adjusted to be substantially equal to the potential of the output signal of the predetermined potential generating section 101.

Thus, selecting the ratio of the resistance value R101a of the resistor 101a to the resistance value R101b of the resistor 101b so that the NMOS transistors 10c, 10d of the sampling section 10 operate in a saturated region can suppress reduction in gain of the sampling section 10, namely can suppress reduction in gain of the latch circuit 1, even if the common potential of the output signals OUT, OUTB of the sampling section 10 varies due to PVT variation etc.

As described above, in the present embodiment, the common potential of the differential input signals SINB, SIN is adjusted so that the NMOS transistors 10c, 10d operate in the saturated region even if, e.g., the common potential of the output signals OUT, OUTB connected to the drains of the NMOS transistors 10c, 10d varies due to PVT variation etc. This can suppress reduction in gain of the latch circuit and the semiconductor device including the same due to PVT variation etc.

The “operation in the saturated region” refers to the operation region where, e.g., the relation given by the following expression (2) is satisfied.

Vds>Vgs−Vthn (2)

In Expression (2), “Vgs” represents a gate-source voltage of an NMOS transistor, “Vds” represents a drain-source voltage thereof, and “Vthn” represents a threshold voltage thereof.

The ratio of the resistance value R101a of the resistor 101a to the resistance value R101b of the resistor 101b can thus be set so that the NMOS transistors 10c, 10d satisfy the above expression (2) even when PVT variation occurs.

### First Modification of First Embodiment

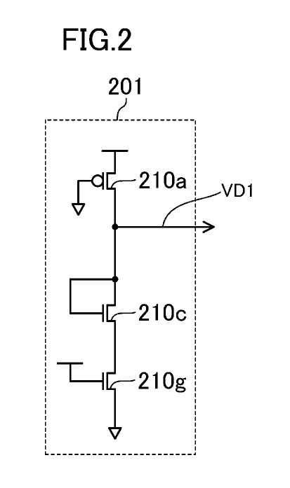

In the first embodiment, the predetermined potential generating section 101 includes the two resistors 101a, 101b. A predetermined potential generating section 201 as shown in FIG. 2 may be used instead of the predetermined potential generating section 101.

In FIG. 2, the predetermined potential generating section 201 includes a PMOS transistor 210a connected between the power supply and the predetermined potential node VD1 as an output node that is connected to the non-inverting input terminal of the differential amplifier 102, and NMOS transistors 210c, 210g connected in series between the predetermined potential node VD1 and the ground. The PMOS transistor 210a is a replica of the load circuit 10a, and the NMOS transistors 210c, 210g are replicas of the NMOS transistors 10c, 10g, respectively. Specifically, the channel length and channel width of the PMOS transistor 210a are substantially the same as those of the PMOS transistor 110a as a replica of the load circuit 10a. The channel lengths and channel widths of the NMOS transistors 210c, 210g are substantially the same as those of the NMOS transistors 110c, 110g as replicas of the NMOS transistors 10c, 10g, respectively. The gate of the PMOS transistor 210a is connected to the ground, and the gate of the NMOS transistor 210g is connected to the power supply.

The NMOS transistor 210c is diode-connected with its gate connected to the predetermined potential node VD 1. A predetermined potential of a signal that is output to the predetermined potential node VD1 is thus a potential that causes the NMOS transistor 110c of the replica sampling section 110 to operate in the saturated region. Specifically, when PVT variation occurs, a signal having a potential varied according to variation in common potential due to the PVT variation, which is a signal that causes the NMOS transistor 110c of the replica sampling section 110 to operate in the saturated region, is applied to the non-inverting input terminal of the differential amplifier 102 which is connected to the predetermined potential node VD1.

The common potential of the output signals OUT, OUTB of the sampling section 10 is thus adjusted to be substantially equal to a potential of a signal that is output from the predetermined potential generating section 201 to the predetermined potential node VD1. The NMOS transistors 10c, 10d of the sampling section 10 therefore operate in the saturated region even when the predetermined potential generating section 201 is used instead of the predetermined potential generating section 101. This can suppress reduction in gain of the latch circuit 1 due to PVT variation etc.

### Second Modification of First Embodiment

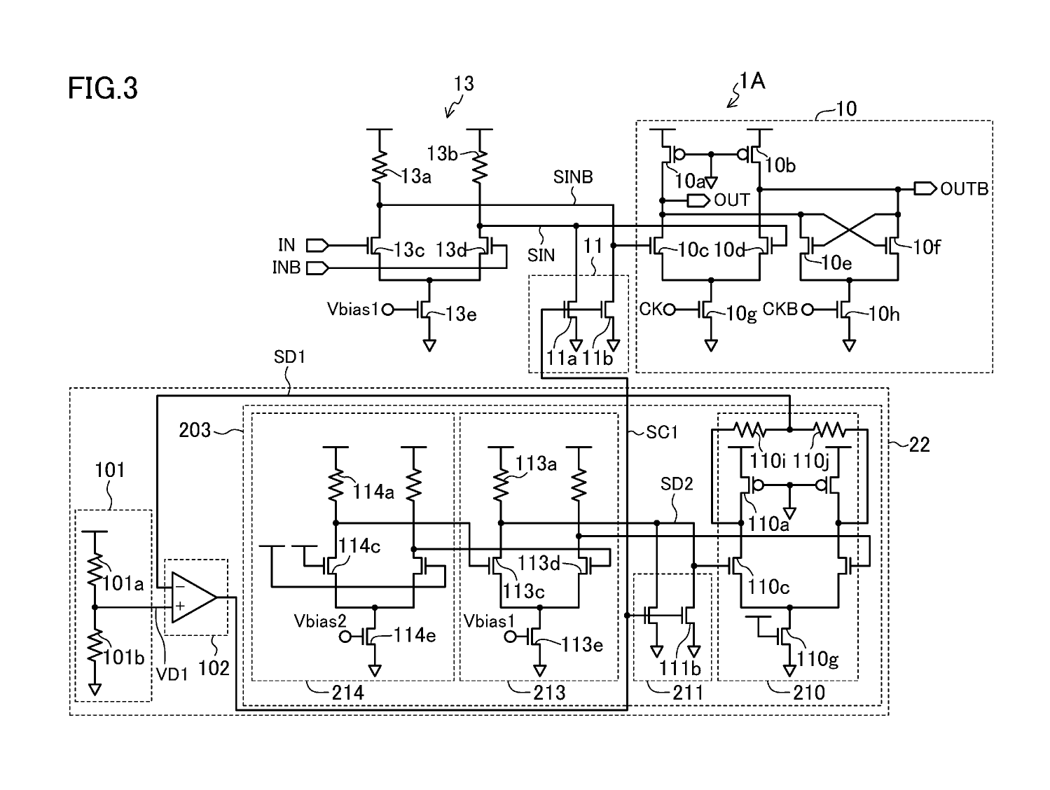

The first embodiment and the first modification thereof use a single configuration as the configuration of the replica section 103 of the common control section 12. However, as shown in FIG. 3, a replica section 203 having a differential configuration may be used instead of the replica section 103 having the single configuration.

In a latch circuit 1A of FIG. 3, a replica portion 203 of a common control section 22 includes a replica sampling section 210, a replica common adjusting section 211, a replica output circuit 213, and a replica 214 of the preamplifier, each having a differential configuration, instead of the replica sampling section 110, the replica common adjusting section 111, the replica output circuit 113, and the replica 114 of the preamplifier. Resistors 110i, 110j configured to detect a common level are connected to an output portion of the replica sampling section 210.

Each transistor in the replica sampling section 210, the replica common adjusting section 211, the replica output circuit 213, and the replica 214 of the preamplifier is designed to have substantially the same channel length and channel width as a corresponding one of the original transistors. Each resistor in the replica sampling section 210, the replica common adjusting section 211, the replica output circuit 213, and the replica 214 of the preamplifier is designed to have substantially the same resistance value as a corresponding one of the original resistors.

By using the replica section 203 having such a differential configuration, variation between any pair of transistors, if any, is averaged and reflected in the current control signal SC1.

This can suppress reduction in gain of the sampling section 10 due to PVT variation etc., and can reduce the influence of the variation between the pair of transistors.

### Second Embodiment

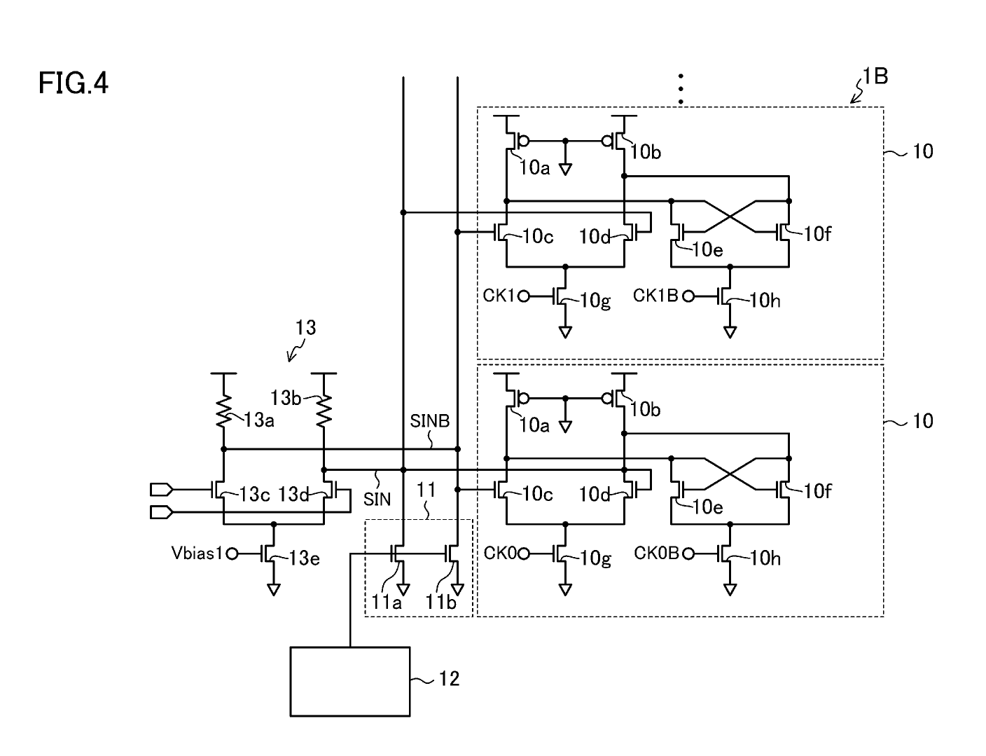

FIG. 4 is a diagram showing a circuit configuration example of a semiconductor device according to a second embodiment of the present disclosure. The semiconductor device of FIG. 4 is different from that of FIG. 1 in that the semiconductor device of FIG. 4 includes a plurality of sampling sections 10.

In a latch circuit 1B of FIG. 4, the gates of the differential pair of transistors 10c, 10d included in each of the plurality of sampling sections 10 are connected in common to the differential input nodes SINB, SIN, respectively. The differential input nodes SINB, SIN are connected in common to the drains of the NMOS transistors 11b, 11a of the common adjusting section 11, respectively. Different clocks CK0, CK1 are applied to the NMOS transistors 10g included in the plurality of sampling sections 10, respectively. Similarly, different clocks CK0B, CK1B are applied to the NMOS transistors 10h included in the plurality of sampling sections 10, respectively. The semiconductor device of FIG. 4 is otherwise similar to that of FIG. 1, and detailed description thereof will be omitted.

The semiconductor device of FIG. 4 can be used in the case where the plurality of sampling sections 10 are required, such as the case where, e.g., oversampling is performed by using clocks having different phases. In this case, the common control section 12 and the common adjusting section 11 can be used by the plurality of sampling sections 10. This can reduce the area as compared to the case where a plurality of common control sections 12 and a plurality of common adjusting sections 11 are provided for the plurality of sampling sections 12.

[Clock Data Recovery System]

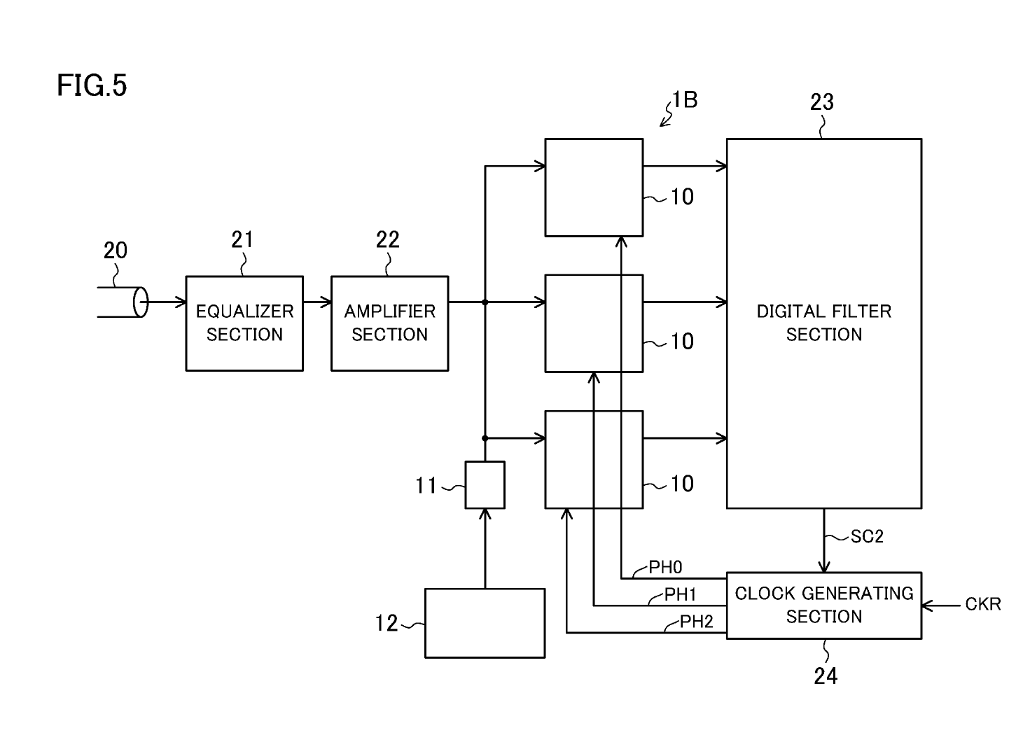

FIG. 5 is a diagram showing an example of a 3-times oversampling clock data recovery system using the latch circuit 1B of FIG. 4.

In FIG. 5, a signal having passed through a transmission path 20 is equalized in waveform by an equalizer section 21, amplified by an amplifier section 22, and then supplied to the sampling sections 10 of the latch circuit 1B. The signals sampled by the sampling sections 10 are supplied to a digital filter section 23.

The digital filter section 23 receives the sampled signals and outputs a phase adjustment signal SC2 to a clock generating section 24. The clock generating section 24 generates clocks PH0, PH1, PH2 that are different in phase from each other, based on a reference clock CKR and the phase adjustment signal SC2, and supplies the clocks PH0, PH1, PH2 to the three sampling sections 10, respectively. In this case, a common potential of the input signals of the three sampling sections 10 is adjusted by the single common adjusting section 11 connected in common to the differential input nodes SINB, SIN and the single common control section 12 that controls the single common adjusting section 11, as in the case of FIG. 4. In the configuration of FIG. 5 as well, the single common adjusting section 11 and the single common control section 12 can be used by the three sampling sections 10 as in the case of FIG. 4.

As described above, the clock data recovery system of the present embodiment can ensure reception performance regardless of PVT variation. Moreover, since the single common adjusting section 11 and the single common control section 12 need only be provided for the three sampling sections 10, the reception performance of the clock data recovery system can be ensured while suppressing an increase in circuit area.

The clock data recovery system is not limited to the configuration of FIG. 5. For example, the clock data recovery system can be implemented without the phase adjustment signal SC2. In this case, a signal selection process is performed in the digital filter section 23 or in a block in a subsequent stage to the digital filter section 23.

Although the clock data recovery system of FIG. 5 uses three sampling sections 10, the present disclosure is not limited to this, and the clock data recovery system may use, e.g., four or more sampling sections 10. In this case as well, the single common adjusting section 11 and the single common control section 12 can be used by the four or more sampling sections 10.

### Third Embodiment

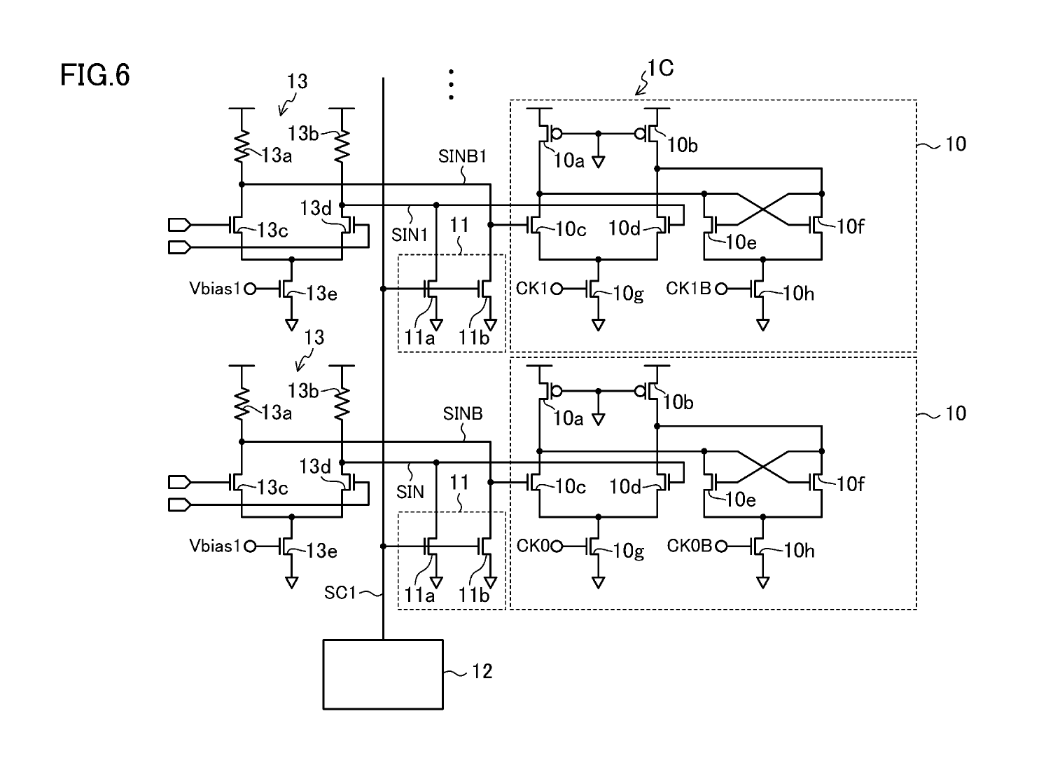

FIG. 6 is a diagram showing a circuit configuration example of a semiconductor device according to a third embodiment of the present disclosure. The semiconductor device of FIG. 6 is different from that of FIG. 1 in that the semiconductor device of FIG. 6 includes a plurality of output amplifiers 13, a plurality of common adjusting sections 11, and a plurality of sampling sections 10.

In the semiconductor device of FIG. 6, the differential input nodes SINB, SIN and differential input node SINB1, SIN1 to which output signals of the plurality of output amplifiers 13 are connected are respectively connected to the gates of the NMOS transistors 10c, 10d of the different sampling sections 10. The drains of the NMOS transistors 11b, 1 la of the different common adjusting sections 11 are respectively connected to the differential input nodes SINB, SIN and the differential input nodes SINB1, SIN1. Different clocks CK0, CK1 are applied to the NMOS transistors 10g in the plurality of sampling sections 10, respectively. Similarly, different clocks CK0B, CK1B are applied to the NMOS transistors 10h in the plurality of sampling sections 10, respectively. The same clock may be applied to the NMOS transistors 10g in each of the sampling sections 10, and the same clock may be applied to the NMOS transistors 10h in each of the sampling sections 10.

The gates of the NMOS transistors 11a, 11b of the plurality of common adjusting sections 11 are connected to a common node. A current control signal SC1 from the single common control section 12 is applied to the common node. Since the current control signal SC1 from the single common control section 12 is applied to the gates of the NMOS transistors 11a, 11b of the plurality of common adjusting sections 11 which are connected to the common node, the single common control section 12 can be used by the plurality of sampling sections 10. This can reduce the area as compared to the case where a plurality of common control sections 12 are provided for the plurality of sampling sections 10.

The above embodiments can be combined as appropriate. For example, the predetermined potential generating section 201 described in the first modification of the first embodiment may be applied to the semiconductor device of FIG. 4 or 6.

The second embodiment may be combined with the third embodiment. Specifically, the configuration in which the differential input nodes connected to the plurality of sampling sections are connected to the single common adjusting section (second embodiment) may be combined with the configuration in which the gates of the NMOS transistors of the plurality of common adjusting sections are connected to the single common control section via the common node (third embodiment).

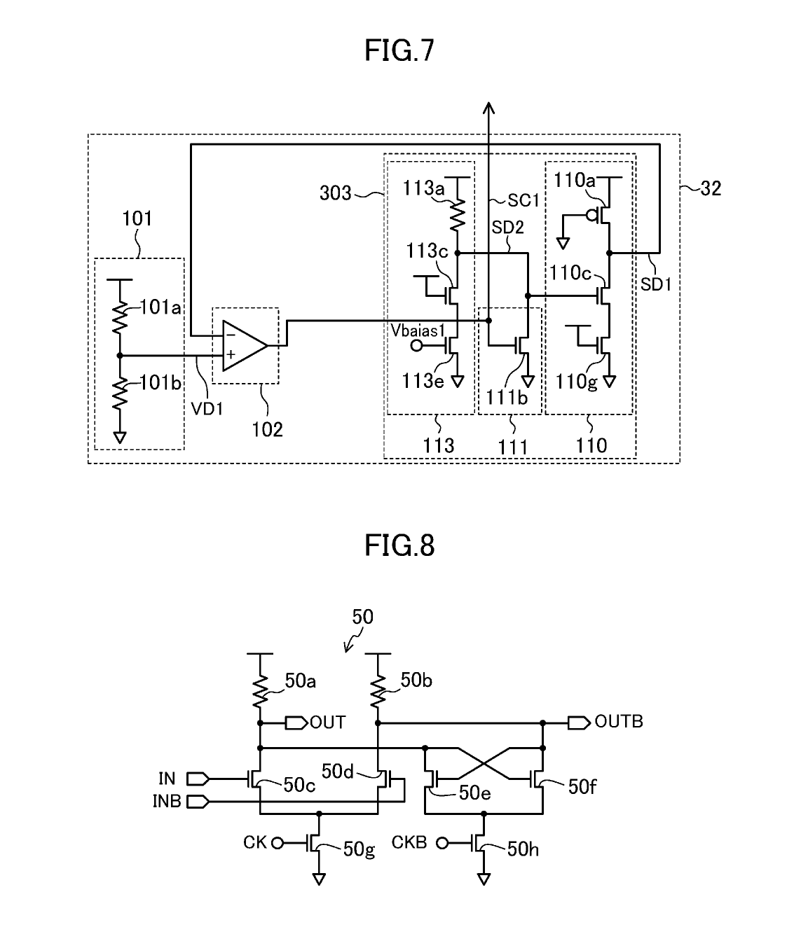

The replica section is not limited to the configurations of FIGS. 1 and 3. For example, the replica section of FIG. 1 may not include the replica 114 of the preamplifier which is provided in the preceding stage to the replica output circuit 113, like a replica section 303 of a common control section 32 shown in FIG. 7. In this case, the gate of the NMOS transistor 113c of the replica output circuit 113 is connected to the power supply. The replica section of FIG. 3 may not include the replica 214 of the preamplifier. In this case, the gates of the NMOS transistors 113c, 113d of the replica output circuit 113 are connected to the power supply.

In the above embodiments, the channel width of each transistor and the resistance value of each resistor in the replica section are designed so as to make a current that is drawn into the common adjusting section substantially equal to a current that is drawn into the replica common adjusting section. However, the present disclosure is not limited to this. For example, in FIG. 7, the resistance value of the resistor 113a may be about n times (n>1) that of the resistor 13a, the channel width of the NMOS transistor 113c, 111b, 110c may be about 1/n times that of the NMOS transistor 13c, 11b, 10c, the channel width of the PMOS transistor 110a may be about 1/n times that of the PMOS transistor 10a, and the channel width of the NMOS transistor 113e, 110g may be about ½n times that of the NMOS transistor 13e, 10g. In this case, the current that is drawn into the replica common adjusting section is about 1/n times the current that is drawn into the common adjusting section. In the above description and the following description, the term “about” includes a margin of error of ±10%.

The resistance value of the resistor 113a may be about 1/m times (m>1) that of the resistor 13a instead of being about n times that of the resistor 13a. The channel width of the NMOS transistor 113c, 111b, 110c may be about m times that of the NMOS transistor 13c, 11b, 10c instead of being about 1/n times that of the NMOS transistor 13c, 11b, 10c. The channel width of the PMOS transistor 110a may be about m times that of the PMOS transistor 10a instead of being about 1/n times that of the PMOS transistor 10a. The channel width of the NMOS transistor 113e, 110g may be about 2m times that of the NMOS transistor 13e, 10g instead of being about ½n times that of the NMOS transistor 13e, 10g. In this case, the current that is drawn into the replica common adjusting section is about m times the current that is drawn into the common adjusting section. It should be understood that the factor for the resistance value is not changed in a circuit in which the replica section does not include any resistor.

In FIG. 6, the above factors for the channel widths of the transistors and for the resistance value of the resistors may vary between the upper stage circuit formed by the output amplifier 13, the common adjusting section 11, and the sampling section 10 of the upper stage and the lower stage circuit formed by the output amplifier 13, the common adjusting section 11, and the sampling section 10 of the lower stage. Specifically, for example, the resistance value of the resistors in the replica section may be about n times that of the resistors in the upper stage circuit, and the resistance value of the resistors in the replica section may be about 1/m times that of the resistors in the lower stage circuit. The channel width of the transistors in the replica section may be about 1/n times and about ½n times that of the transistors in the upper stage circuit, and the channel width of the transistors in the replica section may be about m times and about 2m times that of the transistors in the lower stage circuit.

The sampling section is not limited to the configuration of FIG. 1. For example, in FIG. 1, the PMOS transistors 10a, 10b may be replaced with resistors. In this case, for example, each of the PMOS transistor 110a in the replica sampling section 110 of FIG. 1 and the PMOS transistor 210a in the predetermined potential generating section 201 of FIG. 2 is replaced with a resistor as a replica. The NMOS transistors 10e, 10f and the NMOS transistor 10h that on/off controls the NMOS transistors 10e, 10f may implement a similar data holding function by another circuit configuration.

The output amplifier is not limited to the configuration of FIG. 1. For example, in FIG. 1, the resistors 13a, 13b can be replaced with PMOS transistors having their gates connected to the ground. For example, the output amplifier 13 of FIG. 1 may be implemented by another circuit configured so that the common potential of the output nodes can be adjusted by changing the amount of current flowing in the output nodes (i.e., differential input nodes).

The output amplifier may be provided outside the semiconductor device. In this case, the replica output circuit is designed in view of, e.g., the minimum and maximum values of the amount of current that is output from an output circuit connected thereto to the differential input nodes, the circuit configuration of an output section of the output circuit, etc. In this case, the replica output circuit may configured so that the amount of current flowing in the replica output circuit changes according to a change in amount of current that is output from the output amplifier. Even if the output amplifier is provided outside the semiconductor device, the replica output circuit is desirably a replica based on a part or the whole of the output amplifier.

Although FIG. 5 is described with respect to an example of the clock data recovery system using the latch circuit 1B of FIG. 4, a latch circuit 1C of FIG. 6 may be used in the clock data recovery system.

In the above embodiments, the output amplifier and the sampling section transmit a signal by the NMOS transistors, and the common adjusting section uses the NMOS transistors. However, the output amplifier and the sampling section may transmit a signal by PMOS transistors, and the common adjusting section may use PMOS transistors, although it is preferable that the output amplifier and the sampling section transmit a signal by the NMOS transistors and the common adjusting section use the NMOS transistors.

The semiconductor device and the clock data recovery system according to the present disclosure are useful for, e.g., ultrahigh speed transmission systems with a transmission speed on the order of gigabits per second, etc.

What is claimed is:

1. A semiconductor device, comprising:
a latch circuit, wherein
the latch circuit includes
a sampling section that has a differential pair of transistors having their gates connected to a differential input node, and that latches a differential input signal applied from the differential input node to the gates of the differential pair of transistors,
a common adjusting section that is configured to draw a current from the differential input node, and that adjusts a common potential of the differential input signal by adjusting based on a current control signal an amount of the current that is drawn from the differential input node, and
a common control section that controls the current control signal so that the differential pair of transistors operate in a saturated region, and supplies the controlled current control signal to the common adjusting section.

2. The semiconductor device of claim 1, wherein
the latch circuit includes multiple ones of the sampling section, and
the differential input node connected to the common adjusting section is connected in common to the gates of the differential pairs of transistors of each of the sampling sections.

3. The semiconductor device of claim 1, wherein
the latch circuit includes multiple ones of the sampling section and multiple ones of the common adjusting section,
multiple ones of the differential input node which are respectively connected to the common adjusting sections and which are different from each other are connected to the gates of the differential pairs of transistors of the sampling sections, respectively, and
the common adjusting sections receive the current control signal in common

4. The semiconductor device of claim 1, further comprising:
an output circuit that outputs the differential input signal to the differential input node, wherein
the common adjusting section includes first and second transistors receiving the current control signal at their gates, having their sources connected to a first power supply, and having their drains respectively connected to first and second nodes of the differential input node.

5. The semiconductor device of claim 4, wherein
the common control section includes
a predetermined potential generating section that generates a signal at a predetermined potential to output the generated signal to a predetermined potential node, and
a replica section as a replica of a part or whole of the sampling section, the common adjusting section, and the output circuit, and
the replica section includes
a replica sampling section as a replica of a part or whole of the sampling section, which has a first replica transistor as a replica of one of the differential pair of transistors, the first replica transistor having its drain connected to an output node of the replica section,
a replica common adjusting section as a replica of a part or whole of the common adjusting section, which has a second replica transistor as a replica of one of the first and second transistors, the second replica transistor receiving the current control signal at its gate, having its source connected to the first power supply, and having its drain connected to an output node, and the output node being connected to a gate of the first replica transistor, and
a replica output circuit as a replica of a part or whole of the output circuit, which has an output node connected to the gate of the first replica transistor, and
the common control section further includes
an amplifier that has its one input end connected to an output node of the replica section and the other input end connected the predetermined potential node, and that outputs the current control signal adjusted so as to make potentials at both of the input ends substantially equal to each other.

6. The semiconductor device of claim 5, wherein
in the replica sampling section, the replica common adjusting section, and the replica output circuit, a channel width of the transistor and a resistance value of a resistor are set so as to make an amount of current that is drawn into the replica common adjusting section about 1/n times (n>1) that of current that is drawn into the common adjusting section.

7. The semiconductor device of claim 5, wherein
in the replica sampling section, the replica common adjusting section, and the replica output circuit, a channel width of the transistor and a resistance value of a resistor are set so as to make an amount of current that is drawn into the replica common adjusting section about n times (n>1) that of current that is drawn into the common adjusting section.

8. The semiconductor device of claim 5, wherein
the predetermined potential generating section includes first and second resistors connected in series between the first power supply and a second power supply, and a node between the first and second resistors is connected to the predetermined potential node.

9. The semiconductor device of claim 5, wherein
the sampling section includes
first and second load circuits each having its one end connected to a second power supply and the other end connected to a drain of a corresponding one of the differential pair of transistors, and
a third transistor that receives a first clock signal at its gage to on/off control the differential pair of transistors, and
the predetermined potential generating section includes
a replica of the first or second load circuit which is connected between the second power supply and the predetermined potential node, and
a replica of one of the differential pair of transistors and a replica of the third transistor which are connected in series between the predetermined potential node and the first power supply.

10. The semiconductor device of claim 1, wherein
the sampling section includes
a first transistor that receives a first clock signal at its gate to on/off control the differential pair of transistors,
a second transistor that receives at its gate a second clock signal having an opposite phase to the first clock signal,
a holding circuit that is on/off controlled by the second transistor and that holds data received from the differential pair of transistors, and
a load circuit connected between a second power supply and each of the differential pair of transistors and the holding circuit.

11. A clock data recovery system, comprising:
the semiconductor device of claim 1; and
a digital filter section that receives a signal sampled by the sampling section of the semiconductor device.
